(19) United States
(12) Patent Application Publication
(10) Pub. No.: US 2025/0149429 A1
(43) Pub. Date: May 8, 2025

(54) ELECTRONIC DEVICES AND METHODS OF MANUFACTURING ELECTRONIC DEVICES

(71) Applicant: Amkor Technology Singapore Holding Pte. Ltd.

(72) Inventors: Kyoung Yeon Lee, Incheon (KR); Byong Jin Kim, Seoul (KR); Sang Hyeon Lee, Incheon (KR)

(73) Assignee: Amkor Technology Singapore Holding Pte. Ltd., (omitted)

(21) Appl. No.: 18/504,911

(22) Filed: Nov. 8, 2023

(51) Int. Cl. H01L 23/498; H01L 23/00; H01L 23/36; H01Q 1/22

(52) U.S. Cl. CPC H01L 23/49838; H01L 23/36; H01L 23/49822; H01L 24/16; H01L 24/32; H01L 24/73; H01Q 1/2283; H01L 2224/16227; H01L 2224/32225; H01L 2224/73253

(57) ABSTRACT

In one example, an electronic device comprises a substrate defining an opening between interior sidewalls. An electronic component is disposed in the opening. A lid is disposed beneath the substrate and a first side of the electronic component, and the lid is thermally coupled to the electronic component. Component interconnects can be coupled to a second side of the electronic component opposite the first side. An antenna structure is disposed over the electronic component and electronically coupled to electronic component through the component interconnects. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2E show an example method for manufacturing an electronic device.

FIG. 3 shows a cross-sectional view of an example electronic device.

FIG. 4 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or.” As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements; however, the described elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. As used herein, the term “coupled” can refer to an electrical coupling or a mechanical coupling.

### DESCRIPTION

An example of an electronic device comprises a substrate defining an opening between interior sidewalls. An electronic component is disposed in the opening. A lid is disposed beneath the substrate and a first side of the electronic component, and the lid is thermally coupled to the electronic component. Component interconnects can be coupled to a second side of the electronic component opposite the first side. An antenna structure is disposed over the electronic component and electronically coupled to electronic component through the component interconnects.

Another example electronic device can comprise a substrate including a cavity dielectric having interior sidewalls that define a cavity, and a body dielectric extending between the interior sidewalls of the cavity dielectric and into the cavity. An electronic component is disposed in the cavity, and a first side of the electronic component is exposed from the body dielectric. Component interconnects can be coupled to a second side of the electronic component opposite the first side. An antenna structure can be disposed over the electronic component and electronically coupled to electronic component by the component interconnects.

An example method of making an electronic device comprises the step of providing a cavity substrate comprising interior sidewalls that define a cavity. The cavity substrate comprises a cavity conductor that extends through the cavity substrate. An electronic component is provided between the interior sidewalls and in the cavity. A body dielectric is provided over the cavity substrate, over the electronic device, and in the cavity. A substrate-body conductor is provided and is electrically coupled to the electronic component and extending through the body dielectric. The substrate-body conductor is electrically coupled to the cavity conductor. An antenna structure is provided over the body dielectric. The antenna structure is electrically coupled to the substrate-body conductor.

Other examples are included in the present disclosure. Such examples may be found in the figures, in the claims, or in the description of the present disclosure.

Example devices of the present disclosure tend to improve thermal performance of semiconductor packages. An embedded die can be exposed on the bottom side of the semiconductor package to improve thermal dissipation. A thermally-conductive lid can be attached to the embedded die, or directly attached on a circuit board, to further improve thermal dissipation. An antenna can be included in semiconductor packages of the present disclosure, for example, as an antenna substrate coupled to the top of the package or as a discrete antenna attached on the top of the package.

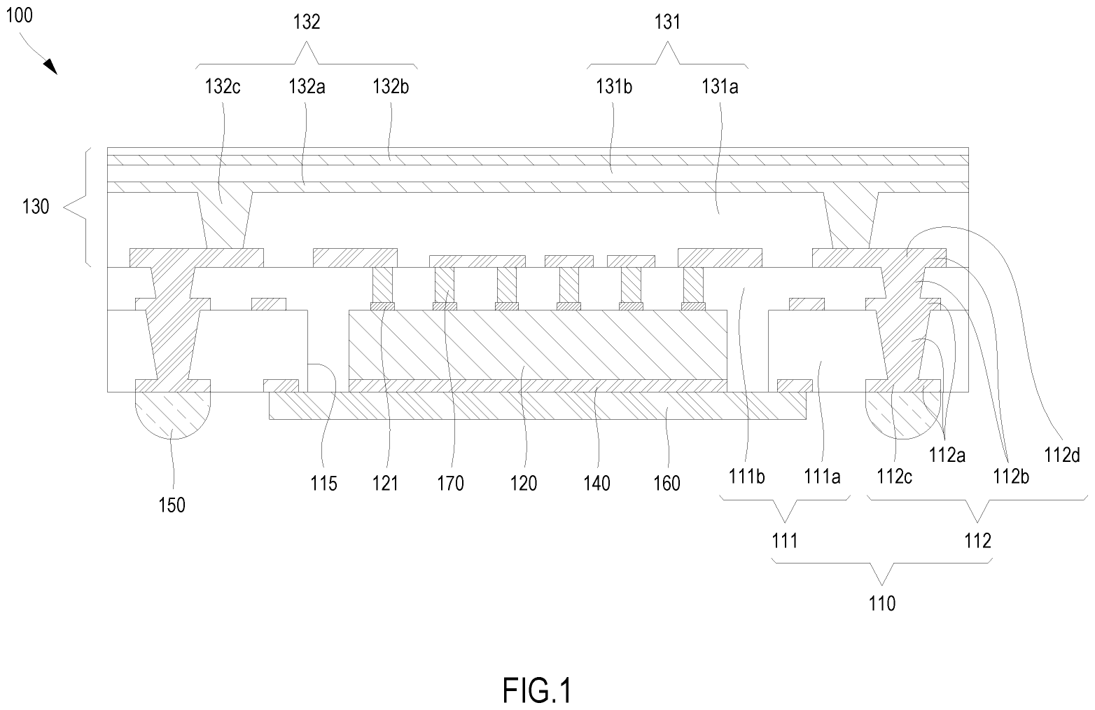

FIG. 1 shows a cross-sectional view of an example electronic device 100. In the example of FIG. 1, electronic device 100 can comprise base substrate 110, electronic component 120, antenna structure 130, die attach material 140, external interconnects 150, lid 160, and substrate-component interconnects 170.

Base substrate 110 can comprise dielectric structure 111, conductive structure 112, and cavity 115. Dielectric structure 111 can comprise cavity dielectric 111a and substrate body dielectric 111b, with interior sidewalls of cavity dielectric 111a defining cavity 115. Conductive structure 112 can comprise cavity conductor 112a and substrate-body conductor 112b. Cavity conductor 112a can comprise substrate outward terminals 112c, and substrate-body conductor 112b can comprise substrate antenna terminals 112d.

Electronic component 120 can comprise component terminals 121. Antenna structure 130 can comprise antenna conductive structure 132 and antenna dielectric structure 131. Antenna conductive structure 132 can comprise inner antenna element 132a, outer antenna element 132b, and antenna interconnects 132c. Antenna dielectric structure 131 can comprise body dielectric 131a and antenna dielectric 131b.

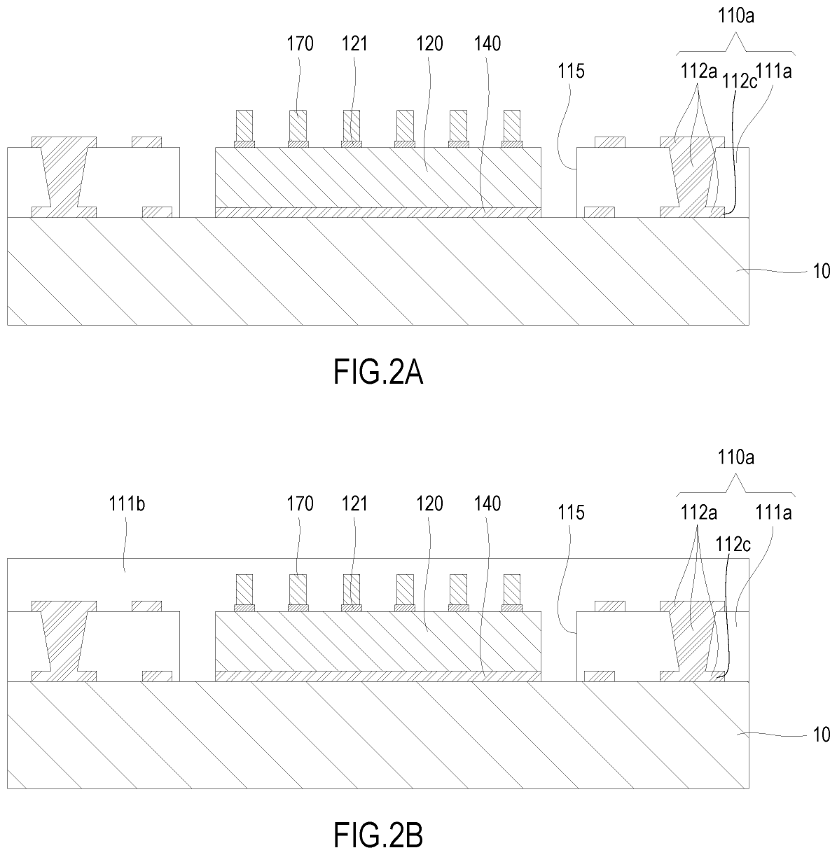

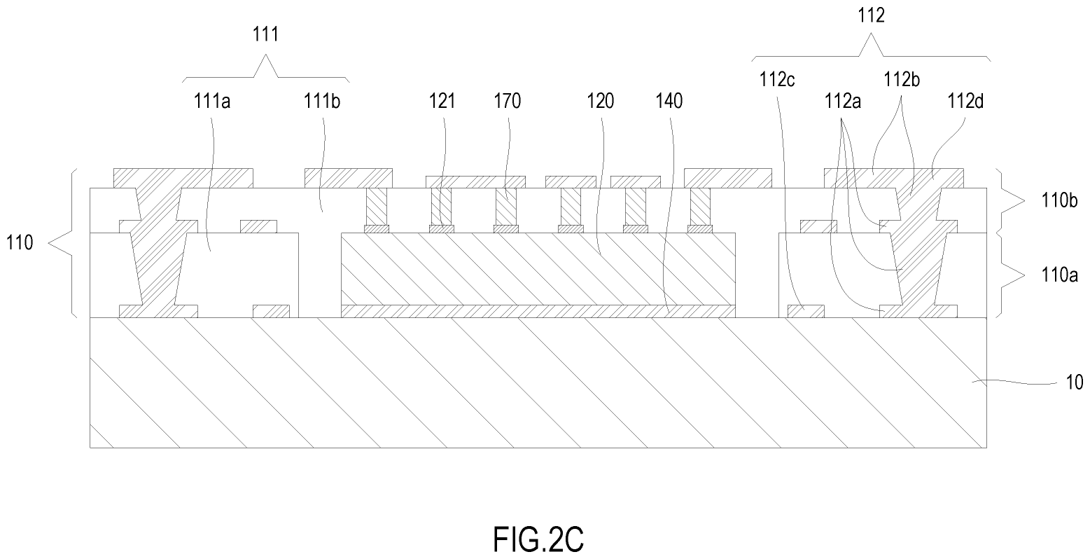

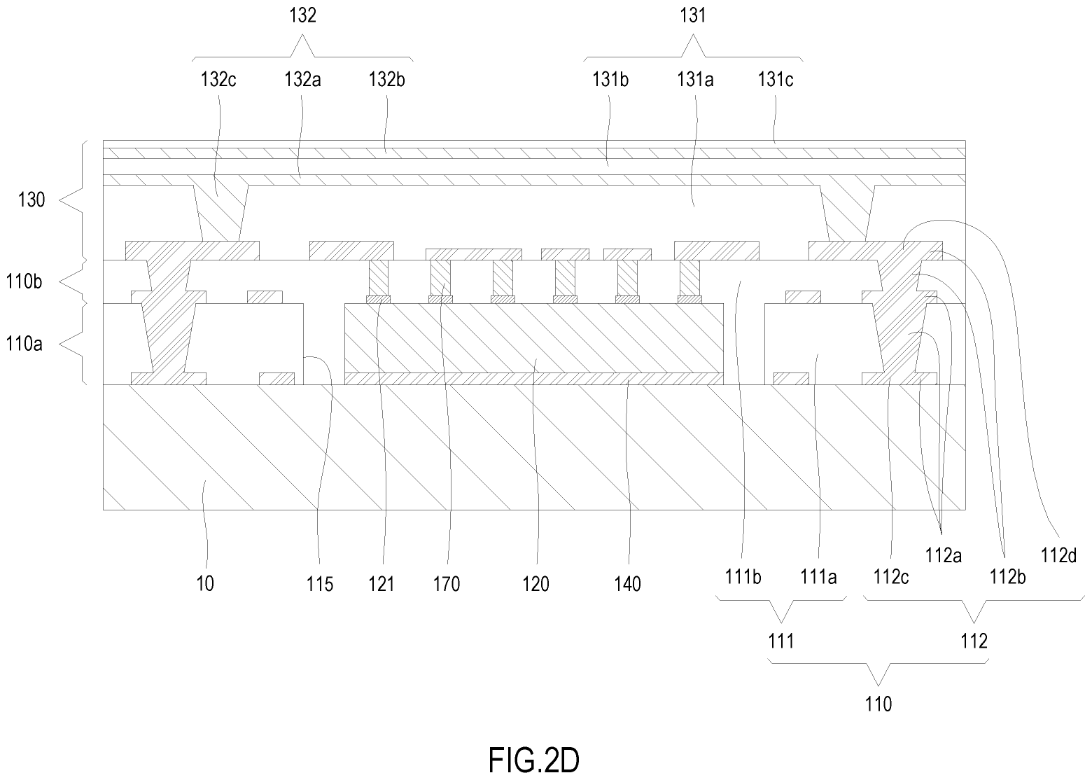

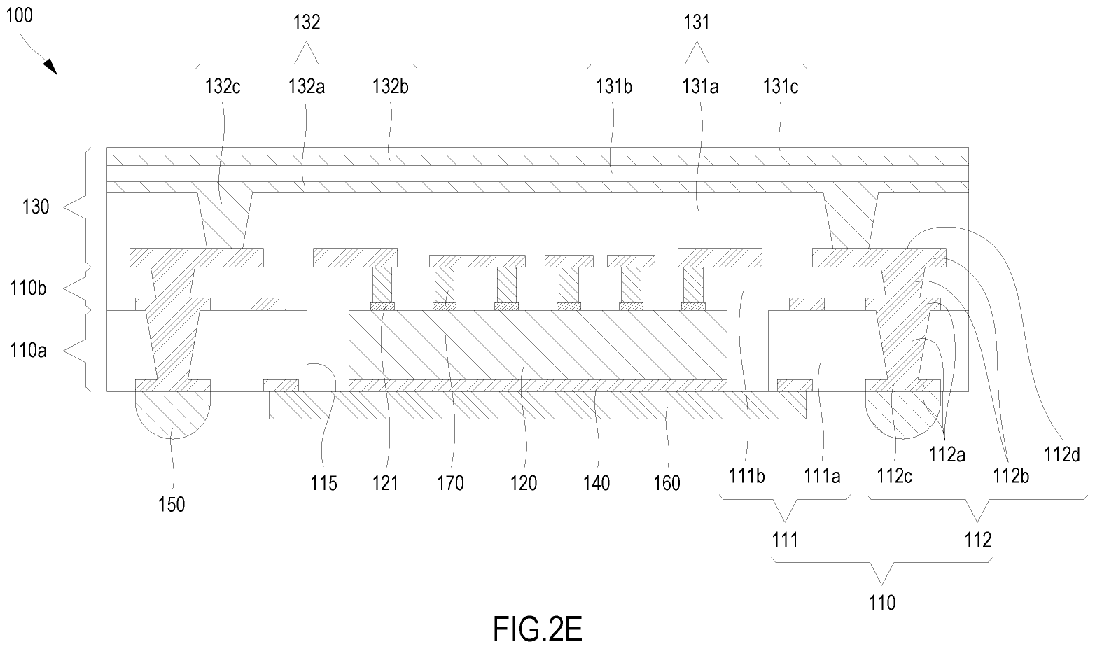

FIGS. 2A to 2E show cross-sectional views of an example method for manufacturing an example electronic device.

FIG. 2A shows a cross section view of electronic device 100 at an early stage of manufacture. In the example shown in FIG. 2A, cavity substrate 110a of base substrate 110 and electronic component 120 can be provided on the upper side of carrier 10. Cavity substrate 110a can comprise cavity dielectric 111a and cavity conductor 112a, and cavity substrate 110a can define cavity 115. In some examples, interior sidewalls of cavity dielectric 111a can define cavity 115. Cavity 115 can extend between the upper and lower sides of cavity substrate 110a and can be located central to cavity substrate 110a. Cavity substrate 110a can have a square or ring-shaped perimeter defining cavity 115 located at the approximate center of cavity substrate 110a. In some examples, the size of cavity 115 can range from approximately 0.1 millimeters (mm)×0.1 mm to 20 mm×20 mm. As used herein with reference to distances or lengths, the term approximately can mean+/−5%, +/−10%, +/−15%, +/−20%, +/−25%.

In various examples, cavity substrate 110a can comprise cavity dielectric 111a and cavity conductor 112a. In some examples, cavity dielectric 111a can comprise or be referred to as one or more stacked dielectric layers. For instance, the one or more dielectric layers can comprise one or more core layers, polymer layers, pre-preg layers, or solder mask layers stacked on each other. In some examples, cavity dielectric 111a can comprise or be referred to as polyimide (PI), benzocyclobutene (BCB), polybenzoxazole (PBO), resin, Ajinomoto Buildup Film (ABF), mold compound, epoxy, silicon, or ceramic. One or more layers or elements of cavity conductor 112a can be interleaved with one or more layers of cavity dielectric 111a. Cavity substrate 110a can comprise an upper side distal to and oriented away from carrier 10 and a lower side opposite the upper side of cavity substrate 110a and oriented toward carrier 10. In some example, the thickness of cavity dielectric 111a can range from approximately 50 micrometers (μm) to 500 μm.

In some examples, cavity conductor 112a can comprise one or more conductive layers and defines conductive paths with elements such as traces, pads, vias, under-bump-metallurgies (UBMs), or wiring patterns. Cavity conductor 112a can provide conductive paths vertically and horizontally through cavity dielectric 111a. In some examples, cavity conductor 112a can comprise copper, iron, nickel, gold, silver, palladium, or tin. Cavity conductor 112a can comprise substrate outward terminals 112c provided at the lower side of cavity substrate 110a.

In various examples, substrate outward terminals 112c can be provided along the lower side of cavity substrate 110a in a matrix form having rows or columns. In some examples, substrate outward terminals 112c can comprise or be referred to as conductors, conductive materials, substrate lands, conductive lands, substrate pads, wiring pads, connection pads, micro pads, or UBMs. In some examples, the thicknesses of substrate outward terminals 112c can range from approximately 5 μm to 100 μm.

In some examples, cavity substrate 110a can comprise or be referred to as a laminate substrate, a ceramic substrate, a rigid substrate, a glass substrate, a silicon substrate, a printed circuit board, a multilayer substrate, or a molded lead frame. In some examples, cavity substrate 110a can comprise or be referred to as a redistribution layer (RDL) substrate, a buildup substrate, or a coreless substrate. In some examples, a thickness of cavity substrate 110a can be similar to or the same as a thickness of electronic component 120. For example, cavity substrate 110a can have a thickness ranging from about 50 μm to about 500 μm.

In some examples, cavity substrate 110a can be an RDL substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, and can include a photolithographic mask through where light is exposed to photo-pattern desired features such as vias in the dielectric layers. The dielectric layers can be made from photo-definable organic dielectric materials such as, for example, PI, BCB, or PBO. Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process.

In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of inorganic dielectric layers can comprise silicon nitride (Si3N4), silicon oxide (SiO2), and/or silicon oxynitride (SiON). The inorganic dielectric layers can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can comprise or be referred to as a coreless substrate. Substrates, as disclosed herein, can comprise RDL substrates.

In some examples, cavity substrate 110a can be a pre-formed substrate. Pre-formed substrates can be manufactured prior to attachment to an electronic device and can comprise dielectric layers interleaved between conductive layers. The conductive layers can comprise copper and can be formed using an electroplating process. The dielectric layers can be relatively thicker non-photo-definable layers; can be attached as a pre-formed film rather than as a liquid; and can include a resin with fillers such as strands, weaves, and/or other inorganic particles for rigidity and/or structural support. Since the dielectric layers can be non-photo-definable, features such as vias or openings can be formed by using a drill or laser. In some examples, the dielectric layers can comprise a prepreg material or ABF. The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate and can omit the permanent core structure. The dielectric and conductive layers can be formed on a sacrificial carrier and is removed after formation of the dielectric and conductive layers and before attachment to the electronic device. The pre-formed substrate can be referred to as a printed circuit board (PCB) or a laminate substrate. Such pre-formed substrates can be formed through a semi-additive or modified-semi-additive process. Substrates, as disclosed herein, can comprise pre-formed substrates.

In accordance with various examples, electronic component 120 can be provided on the upper side of carrier 10. In some examples, electronic component 120 can be located within cavity 115 of cavity substrate 110a. Electronic component 120 can have an upper side oriented away from carrier 10 and a lower side oriented towards carrier 10. In some examples, the upper side of electronic component 120 can comprise or be referred to as an active side, and the lower side of electronic component 120 can comprise or be referred to as an inactive side. In some examples, electronic component 120 can comprise or be referred to as a die, a chip, a package, or a passive component.

In some examples, electronic component 120 can comprise component terminals 121 provided on the upper side. Component terminals 121 of electronic component 120 can be input/output terminals of electronic component 120. In some examples, component terminals 121 can be referred to as or comprise bumps, pads, studs, or pillars. Component terminals 121 of electronic component 120 can be provided spaced apart from each other in a row, column, array, or other configuration on the upper side of electronic component 120. In some examples, an overall thickness of electronic component 120 can be similar to or the same as an overall thickness of cavity substrate 110a. For example, the overall thickness of electronic component 120 can range from approximately 50 μm to approximately 500 μm, and the area of electronic component 120 can range from approximately 1 mm×1 mm to approximately 70 mm×70 mm.

In various examples, component terminals 121 of electronic component 120 can be coupled to substrate-component interconnects 170. In some examples, substrate-component interconnects 170 can comprise or be referred to as vias, pads, lands, UBMs, studs, bumps, pillars, or posts. In some examples, substrate-component interconnects 170 can be provided by performing, on component terminals 121 of electronic component 120, electrolytic plating, electroless plating, sputtering, deposition such as physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). For example, substrate-component interconnects 170 can be provided and coupled to exposed component terminals 121 after providing a photoresist pattern exposing component terminals 121 of electronic component 120 on the upper side of electronic component 120. In some examples, substrate-component interconnects 170 can be provided by forming openings through body dielectric 111b (FIG. 2B) and extending to component terminals 121 of electronic component 120, then providing substrate-component interconnects 170 in the openings.

In some examples, the thicknesses of substrate-component interconnects 170 can range from approximately 10 micrometers (μm) to approximately 300 μm. In some examples, substrate-component interconnects 170 can be parts of electronic component 120 or can be part of conductive structure 112 of base substrate 110.

In some examples, pick-and-place equipment can pick up electronic component 120 and place electronic component 120 inside cavity 115 of cavity substrate 110a. The lower side of electronic component 120 can be fixed to the upper side of carrier 10. The sidewall of electronic component 120 can be spaced apart from the sidewall of cavity dielectric 111a that defines cavity 115 of cavity substrate 110a. Electronic component 120 can be attached to the upper side of carrier 10 using die attach material 140. In some examples, die attach material 140 can be an adhesive or a film. For example, an adhesive die attach material 140 can be applied to the upper side of carrier 10 by dispensing or printing, and electronic component 120 can be placed on die attach material 140 so the lower side of the electronic component 120 is coupled with die attach material 140. In some examples, a film die attach material 140 can be coupled to the lower side of electronic component 120, and the lower side of electronic component 120 can be coupled to the upper side of carrier 10 through die attach material 140. In some examples, die attach material 140 can comprise or be referred to as thermal die attach material (DAM), thermal interface material (TIM), or solder. Die attach material 140 can easily transfer heat generated from electronic component 120 to lid 160 (FIG. 1). The thickness of die attach material 140 can range from approximately 20 μm to approximately 100 μm. The area of die attach material 140 can be similar to an area of electronic component 120.

In various examples, carrier 10 can be a substantially planar plate. In some examples, carrier 10 can comprise or be referred to as a plate, a board, a wafer, a panel, or a strip. Carrier 10 can be made of steel, stainless steel, aluminum, copper, ceramic, glass, or a wafer. In some examples, the thickness of carrier 10 can range from approximately 50 μm to approximately 2000 μm. Carrier 10 can enable integral handling of a plurality of components during a process of providing base substrate 110, electronic component 120, antenna structure 130, die attach material 140, and substrate-component interconnects 170, as discussed below.

In some examples, carrier 10 can comprise a temporary bond layer provided on the upper side of carrier 10. Base substrate 110 and electronic component 120 can be provided on the upper side of the temporary bond layer of carrier 10. The temporary bond layer can be provided by performing, on the upper side of carrier 10, a coating process such as spin coating, doctor blade coating, casting, painting, spray coating, slot die coating, curtain coating, slide coating, or knife over edge coating; by performing a printing process such as screen printing, pad printing, gravure printing, flexography printing, or offset printing, an inkjet printing process; by performing an intermediate technology between coating and printing; or by direct attachment of an adhesive film or an adhesive tape. In some examples, the temporary bond layer can comprise or be referred to as a temporary adhesive film, a temporary adhesive tape, or a temporary adhesive coating. For example, the temporary bond layer can be a heat release tape (film) or an optical release tape (film), the adhesive strength is weakened or removed by heat or light. In some examples, the temporary bond layer can have the adhesive strength weakened or removed by physical and/or chemical external force. The temporary bond layer can allow carrier 10 to be separated from base substrate 110 and electronic component 120 before external interconnects 150 and lid 160 (FIG. 1) are provided, as described below.

FIG. 2B shows a cross section view of electronic device 100 at a later stage of manufacture. In the example shown in FIG. 2B, substrate body dielectric 111b can be provided on the upper side of electronic component 120 and cavity substrate 110a. Substrate body dielectric 111b can cover substrate-component interconnects 170.

In various examples, substrate body dielectric 111b can be coupled to the upper side and sidewalls of electronic component 120, the upper side and sidewalls of substrate-component interconnects 170, the upper side of the cavity substrate 110a, and the sidewalls of cavity substrate 110a defining cavity 115. Substrate body dielectric 111b can fill unoccupied portions of cavity 115. Substrate body dielectric 111b can be provided to cover cavity conductor 112a provided on the upper side of cavity substrate 110a. In some examples, substrate body dielectric 111b can comprise or be referred to as a dielectric layer, a coreless layer, or a filler-free layer. For example, substrate body dielectric 111b can include an electrical insulating material such as prepreg, mold compound, PI, BCB, PBO, resin, or ABF. In some examples, substrate body dielectric 111b can be provided by spin coating, spray coating, dip coating, or rod coating. In some examples, the thickness of substrate body dielectric 111b can range from approximately 60 μm to approximately 800 μm.

FIG. 2C shows a cross section view of electronic device 100 at a later stage of manufacture. In the example shown in FIG. 2C, substrate-body conductor 112b can be provided on the upper side of substrate body dielectric 111b.

In some examples, the upper side of substrate body dielectric 111b and the upper sides of substrate-component interconnects 170 can be coplanar. An upper portion of substrate body dielectric 111b can be removed through planarization, and thus the upper sides of substrate-component interconnects 170 can be exposed from the upper side of substrate body dielectric 111b.

In some examples, an opening exposing cavity conductor 112a can be provided in substrate body dielectric 111b. For example, the opening can be provided by forming a mask pattern on the upper side of substrate body dielectric 111b and then removing exposed portions of substrate body dielectric 111b through etching. In some instances the opening can be referred to as or comprise an aperture or hole.

In various examples, substrate-body conductor 112b can be provided to fill an opening in substrate body dielectric 111b exposing cavity conductor 112a, and substrate-body conductor 112b can extend over an upper side of body dielectric 111b. Substrate body conductor 112b can be coupled to portions of cavity conductor 112a exposed through openings in substrate body dielectric 111b. Substrate body conductor 112b can be coupled to substrate-component interconnects 170 exposed from the upper side of substrate body dielectric 111b. Substrate body conductor 112b can have multiple patterns, and each pattern can be electrically coupled to cavity conductor 112a or substrate-component interconnects 170. Substrate component interconnects 170 can be interposed between component terminals 121 of electronic component 120 and substrate-body conductor 112b of substrate 110. In some examples, substrate-component interconnects 170 can be part of base substrate 110 and can be provided when substrate-body conductor 112b is provided. In some examples substrate-component interconnects 170 can be part of electronic component 120.

In some examples, substrate-body conductor 112b can comprise or be referred to as one or more conductive layer(s), trace(s), pad(s), conductive via(s), RDL, wire pattern(s), or circuit pattern(s). In some examples, substrate-body conductor 112b can comprise copper, iron, nickel, gold, silver, palladium, or tin. In some examples, after a mask pattern is provided to cover the upper side of substrate body dielectric 111b, substrate-body conductor 112b can be provided through plating to fill the openings and the upper side of substrate body dielectric 111b. For example, the mask pattern can use a photoresistor. After substrate-body conductor 112b is provided, the mask pattern can be removed. In some examples, the overall thickness of substrate-body conductor 112b can range from approximately 10 μm to approximately 300 μm.

In various examples, substrate-body conductor 112b can comprise substrate antenna terminals 112d provided in a matrix or array configuration having rows or columns on top of substrate body dielectric 111b. In some examples, the thicknesses of substrate antenna terminals 112d can range from approximately 3 μm to approximately 20 μm.

In some examples, completed base substrate 110 can comprise cavity substrate 110a and body substrate 110b. Body substrate 110b can be positioned above cavity substrate 110a. Cavity substrate 110a can comprise cavity dielectric 111a and cavity conductor 112a, and can define cavity 115. Body substrate 110b can comprise substrate body dielectric 111b and substrate-body conductor 112b. Although body substrate 110b has been described as including one layer of substrate body dielectric 111b and one layer of substrate-body conductor 112b, the number of layers can vary in any substrate described herein. One or more layers or elements of body dielectric 111b can be interleaved with one or more layers or elements of body conductor 112b. Base substrate 110 can include substrate outward terminals 112c and substrate antenna terminals 112d spaced apart from each other rows or columns on the lower and upper sides of base substrate 110.

In various examples, completed base substrate 110 can comprise dielectric structure 111 and conductive structure 112. Dielectric structure 111 can comprise cavity dielectric 111a and substrate body dielectric 111b. Conductive structure 112 can comprise cavity conductor 112a and substrate-body conductor 112b. One or more layers or elements of dielectric structure 111 can be interleaved with one or more layers of conductive structure 112. In some examples, the overall thickness of completed base substrate 110 can range from approximately 60 μm to approximately 800 μm.

FIG. 2D shows a cross section view of electronic device 100 at a later stage of manufacture. In the example shown in FIG. 2D, antenna structure 130 can be provided over the upper side of base substrate 110.

In some examples, antenna structure 130 can comprise dielectric structure 131 and conductive structure 132. Dielectric structure 131 can comprise body dielectric 131a and antenna dielectric 131b. Conductive structure 132 can comprise inner antenna element 132a, outer antenna element 132b, and antenna interconnects 132c. One or more layers or elements of dielectric structure 131 can be interleaved with one or more layers or elements of conductive structure 132.

In various examples, body dielectric 131a can be provided on the upper side of base substrate 110. After body dielectric 131a is provided over or covering substrate-body conductor 112b and substrate body dielectric 111b, an opening exposing substrate-body conductor 112b (e.g., exposing antenna terminals 112d) can be provided in body dielectric 131a. In some examples, body dielectric 131a can comprise an electrically insulating material such as prepreg, mold compound, PI, BCB, resin, or ABF. Elements, features, materials, or manufacturing method of body dielectric 131a can be similar to, or the same as, as those of substrate body dielectric 111b of base substrate 110. Body dielectric 131a can comprise one or more layers. The thickness of body dielectric 131a can range from approximately 20 μm to approximately 500 μm.

In some examples, inner antenna element 132a can be provided over or covering the upper side of body dielectric 131a. Antenna interconnects 132c can be provided to fill one or more opening(s) of body dielectric 131a and contact antenna terminals 112d. Inner antenna element 132a can be coupled to antenna interconnects 132c. Antenna interconnects 132c can electrically connect substrate-body conductor 112b and inner antenna element 132a to each other. Inner antenna element 132a can be electrically coupled to component terminals 121 of electronic component 120 through antenna interconnects 132c, conductive structure 112 of base substrate 110, and substrate-component interconnects 170. In some examples, inner antenna element 132a can comprise or be referred to as a transmitter, a receiver, an antenna, a conductive pattern, or a passive pattern. In some examples, antenna interconnects 132c can comprise or be referred to as vias, lands, or pads. In some examples, inner antenna element 132a and antenna interconnects 132c can comprise copper, gold, or silver. Inner antenna element 132a and antenna interconnects 132c can be integrally provided through plating. In some examples, the thickness of inner antenna element 132a can range from approximately 5 μm to approximately 72 μm, and the thicknesses of antenna interconnects 132c can range from approximately 20 μm to approximately 500 μm.

In various examples, antenna dielectric 131b can be provided over or covering the upper side of inner antenna element 132a. Antenna dielectric 131b can be coupled to the upper side of inner antenna element 132a. Antenna dielectric 131b can comprise one or more layers. Antenna dielectric 131b can include elements, features, materials, or manufacturing method similar to or the same as those of body dielectric 131a.

In some examples, outer antenna element 132b can be provided over or covering the upper side of antenna dielectric 131b. In some examples, outer antenna element 132b can comprise or be referred to as a transmitter, a receiver, an antenna, a conductive pattern, or a passive pattern. Antenna dielectric 131b can be interposed between inner antenna element 132a and outer antenna element 132b. Outer antenna element 132b can include elements, features, materials, or manufacturing method similar to, or the same as, those of inner antenna element 132a.

In some examples, a protective dielectric 131c can be provided over or covering the upper side of outer antenna element 132b. Protective dielectric 131c can be referred to as or comprise a solder mask or insulating material. Protective dielectric 131c can protect outer antenna element 132b from an external environment.

In various examples, completed antenna structure 130 can be a stacked antenna. For example, antenna structure 130 can be a stacked patch antenna. Antenna structure 130 can be an antenna structure using an aperture coupling effect. In antenna structure 130, a radio frequency (RF) signal or other electromagnetic signal can be communicated between inner antenna element 132a and outer antenna element 132b even in examples in which inner antenna element 132a and outer antenna element 132b are electrically isolated from each other. Antenna structure 130 can be electrically coupled to electronic component 120 through base substrate 110 or can be electrically coupled to substrate outward terminals 112c of base substrate 110. The overall thickness of completed antenna structure 130 can range from approximately 25 μm to approximately 500 μm. Antenna structure 130 can be provided by RDL, and an accurate antenna size and pattern can thus be provided by fine-tuning the size (e.g., thickness, pitch, etc.) of the of dielectric and conductive layers of antenna structure 130.

FIG. 2E shows a cross section view of electronic device 100 at a later stage of manufacture. In the example shown in FIG. 2E, external interconnects 150 and lid 160 can be provided on the lower side of base substrate 110 and the lower side of electronic component 120.

In various examples, before providing external interconnects 150 and lid 160 on the lower side of base substrate 110 and the lower side of electronic component 120, carrier 10 can be separated from the lower side of base substrate 110 and the lower side of electronic component 120. In some examples, after the adhesive force of the temporary bond layer interposed between carrier 10 and base substrate 110 and between carrier 10 and electronic component 120 is removed or reduced by applying heat, light, chemical solution, or physical external force, carrier 10 can be separated from the lower side of base substrate 110 and the lower side of electronic component 120. The temporary bond layer of carrier 10 can be separated in a state of being attached to carrier 10. As carrier 10 is removed, the lower side of base substrate 110 and the lower side of electronic component 120 can be exposed. For example, the lower side of die attach material 140 and the lower side of substrate outward terminals 112c of base substrate 110 can be exposed by removal of carrier 10. In some examples, the lower side of electronic component 120 can be exposed. In base substrate 110, the lower side of cavity substrate 110a and the lower side of substrate body dielectric 111b disposed in cavity 115 can be exposed by removal of carrier 10.

In some examples, external interconnects 150 can be coupled to substrate outward terminals 112c of base substrate 110. In some examples, external interconnects 150 can comprise tin (NS), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 150 can be provided through a reflow process after forming a conductive material including solder on substrate outward terminals 112c through a ball drop method. External interconnects 150 can comprise or be referred to as conductive interconnects, such as solder balls, bumps, pads, conductive pillars, or conductive posts having solder caps provided thereon. In some examples, external interconnects 150 can be configured as a ball grid array (BGA) or land grid array (LGA) outside base substrate 110. In some LGA examples, lid 160 and external interconnects 150 can be omitted, and die attach material 140 and substrate 110 can be coupled to a circuit board. In some examples, the size (e.g., height) of external interconnects 150 can range from approximately 25 μm to approximately 500 μm. In some examples, external interconnects 150 can be referred to as external input/output terminals of electronic device 100. External interconnects 150 can be electrically coupled to electronic component 120 or antenna structure 130 through base substrate 110.

In various examples, lid 160 can be provided on or covering the lower side of die attach material 140 or electronic component 120. Die attach material 140 can comprise a thermally conductive material, so heat generated from electronic component 120 can be easily transferred to lid 160. Lid 160 can be a square plate, and the area of lid 160 can be larger than die attach material 140 or electronic component 120. Lid 160 can be coupled to the lower side of electronic component 120 through die attach material 140. Lid 160 can be coupled to substrate outward terminals 112c of base substrate 110. In some examples, one or more substrate outward terminal(s) 112c electrically coupled to lid 160 can be ground terminals. Lid 160 can be coupled to the lower side of the lower side of cavity dielectric 111a and to the lower side of substrate body dielectric 111b exposed through cavity 115.

In some examples, lid 160 can be made of a metal, metal alloy, or other material having a high thermal conductivity. In some examples, lid 160 can comprise aluminum or copper. In some examples, lid 160 can be referred to as or comprise a heat sink, a heat dissipation plate, a cap cover, an encapsulation part, a protection part, or a body. In some examples, trenches, protrusions, or fins can be provided in the lower side of lid 160 to improve heat dissipation efficiency by increasing surface area of lid 160. The thickness of lid 160 can range from approximately 0.1 mm to approximately 4 mm.

Exposing the lower side of electronic component 120 through cavity 115 of base substrate 110 can improve thermal performance of electronic device 100, as heat generated from electronic component 120 can be transferred to lid 160 through die attach material 140, thereby improving heat dissipation performance. In some examples, lid 160 can be omitted, such that the lower side of electronic component 120 or the lower side of die attach material 140 remains exposed in electronic device 100. Exposing the lower side of electronic component 120 or die attach material 140 to the external environment (e.g., air) can increase heat dissipation from electronic component 120 and improve thermal performance of electronic device 100.

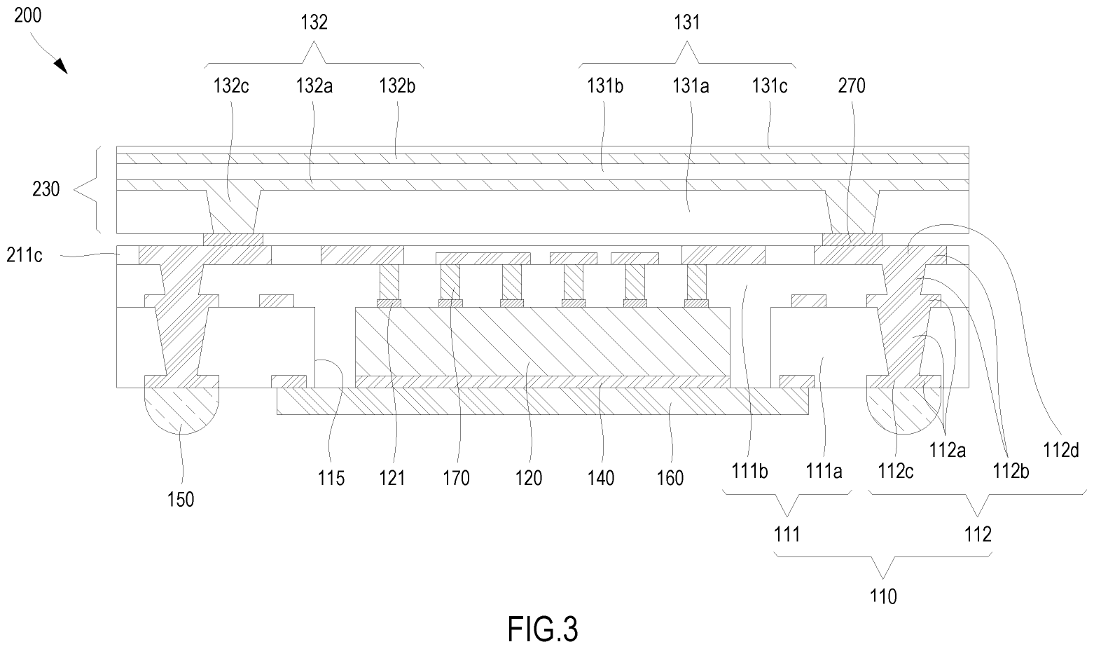

FIG. 3 shows a cross-sectional view of an example electronic device 200. In the example shown in FIG. 3, electronic device 200 can comprise base substrate 110, electronic component 120, antenna structure 230, die attach material 140, external interconnects 150, lid 160, substrate-component interconnects 170, and bond 270.

In various examples, electronic device 200 can be similar to electronic device 100. For example, electronic device 200 can be similar to electronic device 100 in terms of base substrate 110, electronic component 120, die attach material 140, external interconnects 150, lid 160, and substrate-component interconnects 170. Electronic device 200 can comprise protective dielectric 211c, antenna structure 230, and bond 270.

In some examples, protective dielectric 211c can be provided at the upper side of base substrate 110. Protective dielectric 211c can be coupled to the upper side of substrate body dielectric 111b. At least a portion of the upper side of substrate antenna terminals 112d can be exposed from protective dielectric 211c. For example, protective dielectric 211c can include openings exposing substrate antenna terminals 112d. In some examples, protective dielectric 211c can be referred to as or comprise a solder mask or an insulating layer. Protective dielectric 211c can protect the upper side of base substrate 110 from the external environment and prevent bond 270 from leaking onto conductive layers covered by protective dielectric 211c. Protective dielectric 211c can be part of base substrate 110. Protective dielectric 211c can include elements, features, materials, or manufacturing method similar to, or the same as, those of substrate body dielectric 111b. In some examples, the thickness of protective dielectric 211c can range from approximately 5 μm to approximately 72 μm.

In various examples, antenna structure 230 can be coupled to substrate antenna terminals 112d of base substrate 110 through bond 270. In antenna structure 230, the lower side of antenna interconnects 132c can be coupled to the upper sides of substrate antenna terminals 112d of base substrate 110 through bond 270. Antenna structure 230 can be similar to antenna structure 130. In some examples, the lower side of antenna structure 230 can be spaced apart from the upper side of base substrate 110 by a distance approximately equal to the thickness of bond 270. Bond 270 can be interposed between antenna structure 230 and base substrate 110. Bond 270 can be interposed between antenna interconnects 132c of antenna structure 230 and substrate antenna terminals 112d of base substrate 110. The lower side of body dielectric 131a can be spaced apart from the upper side of base substrate 110.

In accordance with various examples, antenna structure 230 can be formed discretely from base substrate 110. Once formed, antenna structure 230 can be picked up and placed over base substrate 110. For example, antenna interconnects 132c can be placed on the upper side of substrate antenna terminals 112d and can be coupled to substrate antenna terminals 112d through bond 270. In some examples, bond 270 can comprise solder, a conductive adhesive, a conductive paste, or a conductive film. In some examples, the thickness of bond 270 can range from approximately 5 μm to approximately 50 μm. Antenna structure 230 being discrete from base substrate 110 allows antenna structure 230 to be tested prior to attachment to base substrate 110, which can increase throughput of know good devices.

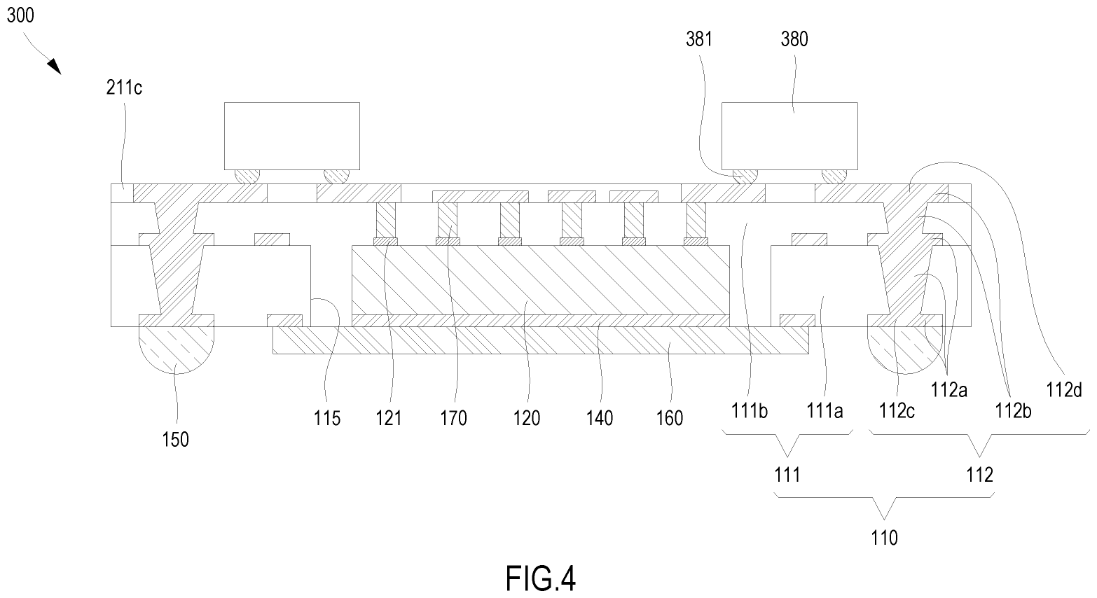

FIG. 4 shows a cross-sectional view of an example electronic device 300. In the examples shown in FIG. 4, electronic device 300 can comprise base substrate 110, electronic component 120, die attach material 140, external interconnects 150, lid 160, substrate-component interconnects 170, and one or more mounted module(s) 380.

In various examples, electronic device 300 can be similar to electronic device 100 and electronic device 200. For example, electronic device 300 can be similar to electronic device 100 in terms of base substrate 110, electronic component 120, die attach material 140, external interconnects 150, lid 160, and substrate-component interconnects 170. Electronic device 300 can be similar to electronic device 200 in terms of protective dielectric 211c. Electronic device 300 can comprise mounted module(s) 380.

Mounted module 380 can comprise module interconnects 381 on the lower side of mounted module 380. Mounted module 380 can be coupled to substrate antenna terminals 112d through module interconnects 381. Module interconnects 381 can be input/output terminals of mounted module 380. In some examples, one or more of the mounted module(s) 380 can be an antenna component and can include one or more transmitter(s), receiver(s), or other antenna elements. In some examples, one or more of the mounted module(s) 380 can be an electronic component such as a die, a chip, a package, or a passive component. Mounted module 380 can be placed on the upper side of base substrate 110 through pick-and-place equipment. Module interconnects 381 of mounted module 380 can be coupled to the upper side of substrate antenna terminals 112d of base substrate 110. Mounted module(s) 380 can be electrically coupled to electronic component 120 or external interconnects 150 through base substrate 110. In some examples, the thickness of mounted module 380 can range from approximately 90 μm to approximately 500 μm.

The examples electronic devices and methods of making electronic devices described above tend to result in improved thermal performance. A thermally conductive lid can be coupled to a thermal die attach material or electronic component to dissipate heat generated during operation of the electronic component. The lid can be coupled to lower terminals of a base substrate. An antenna can be included in the electronic device and can be in thermal communication with the lid to improve heat dissipation.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

1. An electronic device, comprising:
a substrate defining an opening between interior sidewalls;
an electronic component disposed in the opening;
a lid disposed beneath the substrate and a first side of the electronic component, wherein the lid is thermally coupled to the electronic component;
component interconnects coupled to a second side of the electronic component opposite the first side; and
an antenna structure disposed over the electronic component and electronically coupled to electronic component through the component interconnects.

2. The electronic device of claim 1, wherein the substrate comprises:
a cavity dielectric including the interior sidewalls that define the opening; and
a body dielectric disposed over the electronic component and between the electronic component and the interior sidewalls of the cavity dielectric.

3. The electronic device of claim 2, wherein the component interconnects comprise pillars formed over the second side of the electronic component before the body dielectric is provided over the electronic component.

4. The electronic device of claim 1, wherein the antenna structure comprises an antenna substrate.

5. The electronic device of claim 4, wherein the antenna structure is electronically coupled to the substrate through a bond, wherein the bond separates the antenna structure from the substrate by a thickness of the bond.

6. The electronic device of claim 1, wherein the antenna structure is patterned over the substrate.

7. The electronic device of claim 1, wherein the antenna structure comprises a second electronic component coupled to a side of the substrate opposite the lid.

8. The electronic component of claim 1, wherein the lid is coupled to the electronic component by a thermal die attach material.

9. An electronic device, comprising:
a substrate comprising:
a cavity dielectric having interior sidewalls that define a cavity; and
a body dielectric extending between the interior sidewalls of the cavity dielectric and into the cavity;
an electronic component disposed in the cavity, wherein a first side of the electronic component is exposed from the body dielectric;
component interconnects coupled to a second side of the electronic component opposite the first side; and
an antenna structure disposed over the electronic component and electronically coupled to electronic component by the component interconnects.

10. The electronic device of claim 9, further comprising a die attach material coupled to the first side of the electronic component exposed from the body dielectric.

11. The electronic device of claim 10, further comprising a lid disposed beneath the substrate and a first side of the electronic component, wherein the die attach material thermally couples the lid to the electronic component.

12. The electronic device of claim 9, wherein the antenna structure is formed over the electronic component and the substrate.

13. The electronic device of claim 9, wherein the electronic component is embedded in the substrate.

14. A method of making an electronic device, comprising:
providing a cavity substrate comprising interior sidewalls that define a cavity, wherein the cavity substrate comprises a cavity conductor that extends through the cavity substrate;
providing an electronic component between the interior sidewalls and in the cavity;
providing a body dielectric over the cavity substrate, over the electronic device, and in the cavity;
providing a substrate-body conductor electrically coupled to the electronic component and extending through the body dielectric, wherein the substrate-body conductor is electrically coupled to the cavity conductor; and
providing an antenna structure over the body dielectric, wherein the antenna structure is electrically coupled to the substrate-body conductor.

15. The method of claim 14, further comprising:
providing a die attach material in the cavity;
providing the electronic component over a first side of the die attach material; and
providing a lid coupled to a second side of the die attach material opposite the first side.

16. The method of claim 14, further comprising:
providing substrate-component interconnects coupled to an active side of the electronic component; and
providing the body dielectric around the substrate-component interconnects.

17. The method of claim 14, further comprising:
forming openings through the body dielectric to an active side of the electronic component; and
providing substrate-component interconnects in the openings.

18. The method of claim 14, wherein providing the antenna structure further comprises:
forming the antenna structure; and
providing the formed antenna structure over the body dielectric.

19. The method of claim 17, wherein the antenna structure comprise a second electronic component.

20. The method of claim 14, wherein providing the antenna structure further comprises forming the antenna structure over the substrate-body conductor.
